(19) United States
(12) Patent Application Publication
(10) Pub. No.: US 2026/0130270 A1
(43) Pub. Date: May 7, 2026

(54) PACKAGE STRUCTURE AND MANUFACTURING METHOD THEREOF

(71) Applicant: Powertech Technology Inc., Hsinchu County (TW)

(72) Inventors: Shang-Yu Chang Chien, Hsinchu County (TW); Yi-Kai Fu, Hsinchu County (TW)

(73) Assignee: Powertech Technology Inc., Hsinchu County (TW)

(21) Appl. No.: 19/363,541

(22) Filed: Oct. 20, 2025

(30) Foreign Application Priority Data
Nov. 6, 2024 (TW) 113142462

(51) Int. Cl. H01L 23/31; H01L 21/56; H01L 23/00; H01L 23/15; H01L 23/49; H01L 23/498; H01L 23/538; H01L 25/065

(52) U.S. Cl. CPC H10W 74/117; H10W 70/611; H10W 70/635; H10W 72/50; H10W 74/012; H10W 74/15; H10W 90/00; H10W 90/701; H10W 70/692; H10W 90/724; H10W 90/734

(57) ABSTRACT

A package structure includes a substrate, an interposer module, a chip module, and a first encapsulant. The interposer module is arranged on the substrate. The chip module is arranged on the interposer module. The chip module is electrically connected to the substrate through the interposer module. The first encapsulant encapsulates the chip module and the interposer module and directly contacts the substrate. A bottom surface of the first encapsulant and a top surface of the substrate are coplanar. A manufacturing method of a package structure is also disclosed.

### CROSS-REFERENCE TO RELATED APPLICATION

This application claims the priority benefit of Taiwan application serial no. 113142462, filed on Nov. 6, 2024. The entirety of the above-mentioned patent application is hereby incorporated by reference herein and made a part of this specification.

### BACKGROUND

### Technical Field

The present disclosure relates to a package structure and a manufacturing method thereof.

### Description of Related Art

With the advancement of technology, market demands for electronic products have become increasingly stringent. Consequently, ensuring the superior quality of package structures has emerged as a critical subject of current research and development endeavors.

### SUMMARY

The present disclosure provides a package structure and a manufacturing method thereof, through which the yield may be effectively improved, thereby ensuring good quality of the package structure.

A package structure of the present disclosure includes a substrate, an interposer module, a chip module, and a first encapsulant. The interposer module is disposed on the substrate. The chip module is set on the interposer module. The chip module is electrically connected to the substrate through the interposer module. The first encapsulant encapsulates the chip module and the interposer module and directly contacts the substrate. The bottom surface of the first encapsulant is coplanar with the top surface of the substrate.

A manufacturing method of a package structure of the present disclosure at least includes: providing a substrate; providing an interposer module in a singulated manner; disposing the interposer module on the substrate; providing a chip module; disposing the chip module on the interposer module, causing the chip module to be electrically connected to the substrate through the interposer module; and forming a first encapsulant to encapsulate the chip module and the interposer module and directly contact the substrate.

Based on the above, since the number of manufacturing process steps that the chip module goes through may be reduced, the risk of defect rate in the process may be lowered. At the same time, based on the protection of the encapsulant, the overall structural strength may be improved. Accordingly, the yield of the package structure of the present disclosure may be effectively improved, thereby ensuring good quality of the package structure.

To make the above-mentioned features and advantages of the present disclosure more evident and easy to understand, exemplary embodiments are described below with reference to the accompanying drawings in detail as follows.

### BRIEF DESCRIPTION OF THE DRAWINGS

FIG. 1A to FIG. 1G are partial cross-sectional schematic views of a partial manufacturing method of a package structure according to an embodiment of the present disclosure.

FIG. 2, FIG. 3, FIG. 4, FIG. 5, FIG. 6, FIG. 7, FIG. 8, FIG. 9, FIG. 10, FIG. 11, FIG. 12, and FIG. 13 are partial cross-sectional schematic views of package structures according to some embodiments of the present disclosure.

### DESCRIPTION OF THE EMBODIMENTS

The directional terms (e.g., upper, lower, right, left, front, back, top, bottom) used in this document are only for reference to the accompanying drawings and are not intended to imply absolute orientation.

Unless explicitly stated otherwise, any method described herein may not be construed as requiring its steps to be performed in a specific order.

Refer to the drawings of this embodiment to more comprehensively illustrate the present disclosure. However, the present disclosure may also be embodied in various different forms and should not be limited to the embodiments described herein. The thickness, dimensions or size of layers or areas in the drawings may be exaggerated for clarity. The same or similar reference numbers indicate the same or similar components, which will not be described repeatedly in the following paragraphs.

It should be understood that although the terms “first”, “second”, “third”, etc. may be used herein to describe various components, parts, areas, layers and/or portions, these components, parts, areas, layers and/or portions should not be limited by these terms. These terms are only used to distinguish one component, part, area, layer or portion from another component, part, area, layer or portion.

Unless otherwise stated, the term “between” used in this specification for defining numerical ranges is intended to cover ranges equal to the stated endpoint values as well as ranges between the stated endpoint values. For example, a dimensional range between a first value and a second value means that the dimensional range may cover the first value, the second value, and any value between the first value and the second value.

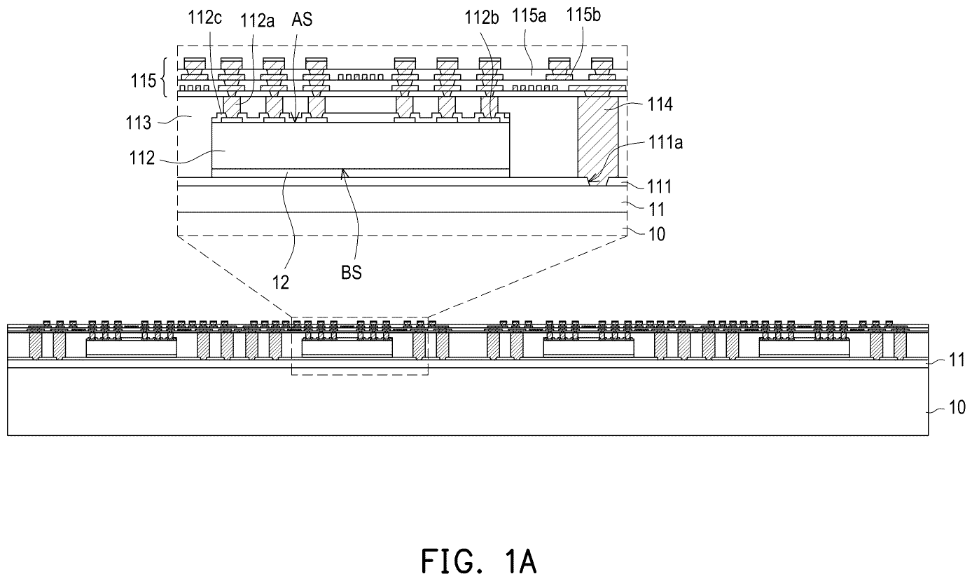

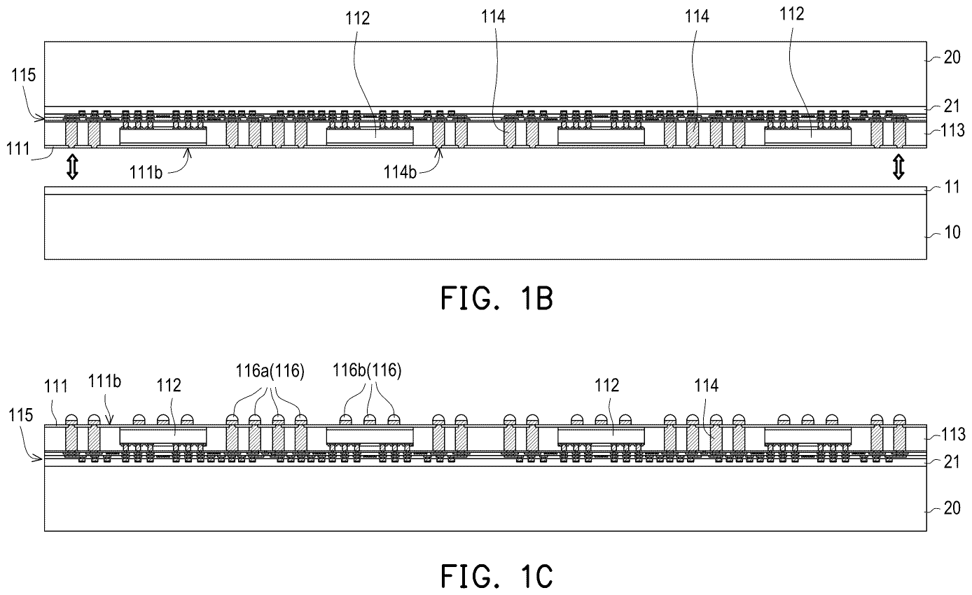

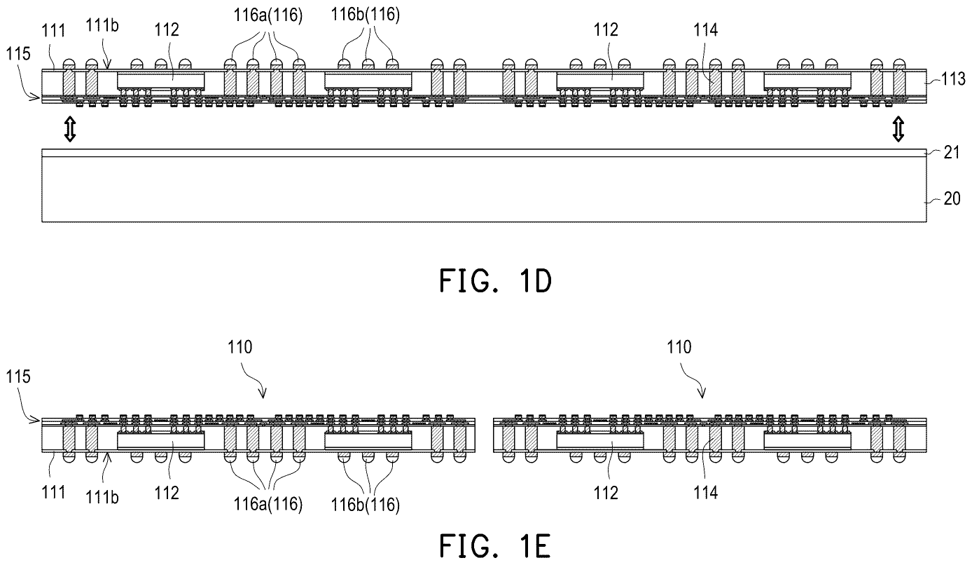

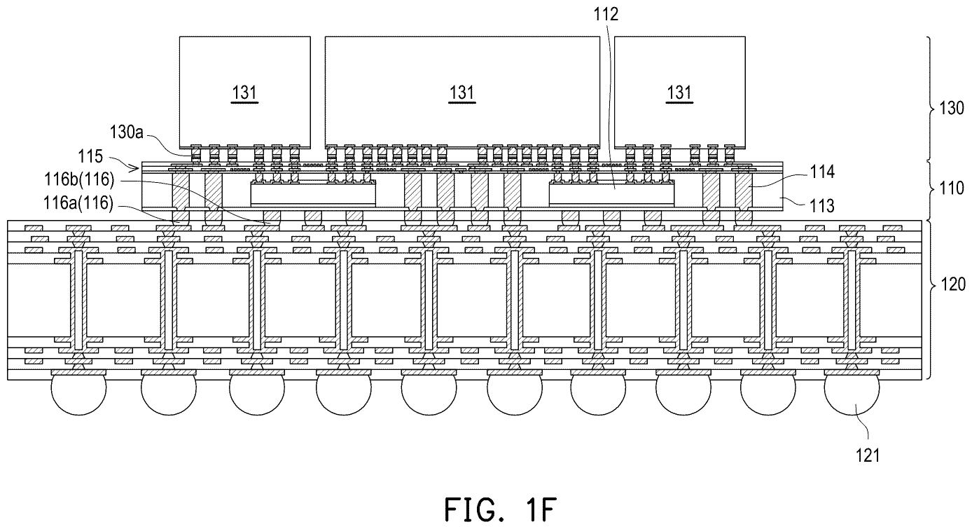

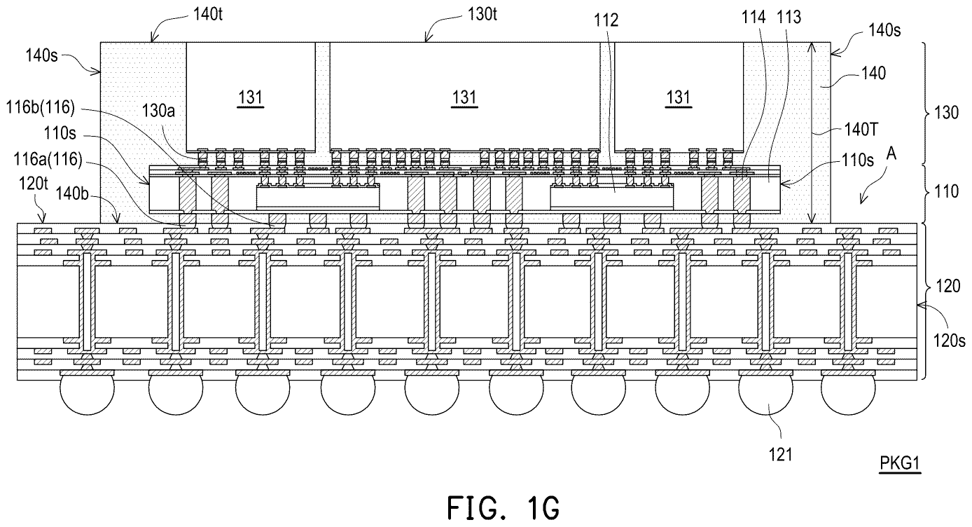

FIG. 1A to FIG. 1G are partial cross-sectional schematic views of a partial manufacturing method of a package structure according to an embodiment of the present disclosure. Referring to FIG. 1A to FIG. 1E, the manufacturing process of the interposer module 110 may include the following steps. First, a carrier 10 is provided. In some embodiments, the carrier 10 may be, for example, a board made of glass, wafer, metal or other suitable supporting materials, so that the carrier 10 may be used to support layers or components formed thereon.

In this embodiment, a release layer 11 may optionally be formed on the carrier 10 to improve the releasability between the structure (such as the intermediate structure in the process) and the carrier 10 in the subsequent manufacturing process. For example, the release layer 11 may be a light-to-heat-conversion (LTHC) release layer or other suitable release layer, but the present disclosure is not limited thereto. In present embodiment, the release layer 11 may not provide adhesion function.

Next, a layered structure 111 is formed on the carrier 10, wherein in this embodiment, the layered structure 111 is a single-layer structure. For example, the layered structure 111 may be an insulating layer deposited from materials such as polyimide, polybenzoxazole (PBO), benzocyclobutene (BCB) or the like, but the present disclosure is not limited thereto. In an embodiment not shown, the layered structure 111 may be a suitable multi-layer redistribution layer (RDL) structure, wherein the topmost layer and the bottommost layer of the multi-layer redistribution layer structure are insulating layers deposited from materials such as polyimide, PBO, BCB or the like. In addition, multiple openings 111a may be formed in the layered structure 111 through appropriate means (such as an etching process).

Then, as shown in FIG. 1A, multiple bridge chips 112 are disposed on the carrier 10. In this embodiment, the bridge chip 112 has an active surface AS and a back surface BS opposite to the active surface AS, and the bridge chip 112 is configured on the layered structure 111 with the active surface AS facing upward. For example, the back surface BS of the bridge chip 112 may be attached to the layered structure 111 by means of an adhesive layer 12, and the adhesive layer 12 may directly contact the top surface of the layered structure 111.

In an embodiment, the adhesive layer 12 may be a die attach film (DAF). However, the present disclosure is not limited thereto. In other embodiments, the bridge chip 112 may be configured on the carrier 10 in other ways. Furthermore, the bridge chip 112 may be any suitable type of chip.

After configuring multiple bridge chips 112, an encapsulant 113 is formed to encapsulate the multiple bridge chips 112 (for example, directly contacting the silicon substrate of the bridge chips 112). In an embodiment, the encapsulant 113 may be formed by the following steps. First, a packaging material is formed to cover the conductive bump 112a of the bridge chip 112, wherein the conductive bump 112a may be configured on the pad 112b and surrounded by the insulating layer 112c. Next, a planarization process is performed on the packaging material to form the encapsulant 113, so that the top surface of the encapsulant 113 may be substantially coplanar with the top surface of the conductive bump 112a, but the present disclosure is not limited thereto. Here, the encapsulant 113 is, for example, a second encapsulant.

In FIG. 1A, multiple conductive connecting components 114 may also be formed on the carrier 10, wherein the multiple conductive connecting components 114 may correspond to the multiple openings 111a of the layered structure 111 and surround the bridge chip 112, wherein the multiple conductive connecting components 114 and the multiple openings 111a are, for example, disposed in a one-to-one manner. Furthermore, the top surface of the conductive connecting components 114, the top surface of the encapsulant 113, and the top surface of the conductive bump 112a may be substantially coplanar, but the present disclosure is not limited thereto.

In some embodiments, the material of the conductive connecting components 114 may include copper, aluminum, nickel, or combinations thereof, and may be, for example, a conductive pillar formed by means of lithography, plating, or photoresist stripping. However, the present disclosure is not limited thereto, and the conductive connecting components 114 may be formed by other suitable materials and formation methods according to actual design requirements.

In an embodiment, the conductive connecting components 114 are formed before disposing the multiple bridge chips 112 and forming the encapsulant 113. In another embodiment, the conductive connecting components 114 are formed after disposing the multiple bridge chips 112 and before forming the encapsulant 113. In yet another embodiment, the conductive connecting components 114 are formed after disposing the multiple bridge chips 112 and forming the encapsulant 113.

Please continue to refer to FIG. 1A, a circuit layer 115 is formed on the carrier 10 (for example, directly contacting the encapsulant 113 and the conductive connecting components 114). In this embodiment, the circuit layer 115 may be a multi-layer structure. For example, the circuit layer 115 may include multiple dielectric layers 115a and multiple patterned conductive layers 115b stacked on each other, wherein the patterned conductive layers 115b may be used for redistribution of the wires for signal transmission of the packaging.

In some embodiments, the material of the dielectric layers 115a may include silicon oxide, silicon nitride, silicon carbide, silicon oxynitride, polyimide, benzocyclobutene, and may be formed by means of spin-on coating, chemical vapor deposition (CVD), or plasma-enhanced chemical vapor deposition (PECVD).

In some embodiments, the material of the patterned conductive layers 115b may include copper, aluminum, nickel, gold, silver, tin, or combinations thereof, and may be formed by means of sputtering, evaporation, electro-less plating, or electroplating. However, the present disclosure is not limited thereto, and the dielectric layers 115a and the patterned conductive layers 115b may be formed by other suitable materials and formation methods according to actual design requirements.

Please refer to FIG. 1B, after forming the circuit layer 115, another carrier 20 and another release layer 21 are joined on the circuit layer 115, wherein part of the circuit layer 115 may be optionally embedded in the release layer 21. Then, the carrier 10 is removed through the release layer 11 to expose the bottom surface 111b of the layered structure 111 and the bottom surface 114b of the conductive connecting components 114, wherein the carrier 20 and the release layer 21 are similar to the carrier 10 and the release layer 11, and will not be described again here. Here, the release layer 11 and the carrier 10 may be exposed to UV laser, causing the release layer 11 and the carrier 10 to be peeled off and separated from the layered structure 111 and the conductive connecting components 114. In present embodiment, the release layer 21 may not provide adhesion function, for this reason, an adhesive layer (not shown) may be formed between the circuit layer 115 and the release layer 21.

Please refer to FIG. 1C, the structure shown in FIG. 1B is flipped upside down, so that multiple bridge chips 112, the encapsulant 113, and the conductive connecting components 114 are shown to be configured on the circuit layer 115. Then, multiple connecting terminals 116 are formed on the bottom surface 114b of the conductive connecting components 114 and the bottom surface 111b of the layered structure 111.

For example, as shown in FIG. 1C, the connecting terminals 116 include multiple conductive terminals 116a and multiple dummy terminals 116b, wherein the conductive terminals 116a may directly contact and electrically connect with the conductive connecting components 114, while the dummy terminals 116b may directly contact and be electrically insulated from the layered structure 111. Here, the dummy terminals 116b may be dummy bumps. By means of the design of these dummy terminals 116b, in embodiments using electroplating process to fabricate terminals, it is possible to make the distribution of terminals on the entire plane requiring electroplating more uniform, so as to obtain a more uniform electroplating current distribution, thereby the height of the formed terminals will also be more uniform. In this way, good terminal co-planarity may be achieved. Alternatively, by means of the design of these dummy terminals 116b, it is possible to achieve the function of dispersing stress, so that under situations with temperature differences such as high and low temperature changes and/or reliability tests generated during subsequent component operation, it is possible to avoid the stress caused by thermal expansion coefficient (CTE) mismatch from acting entirely on the functional conductive terminals 116a, thereby effectively improving the lifespan and performance of the product, while also enhancing the performance of the product in reliability tests. However, the present disclosure is not limited thereto.

Please refer to FIG. 1D, after forming the connecting terminals 116, the carrier 20 is removed through the release layer 21 to expose another surface of the circuit layer 115 relative to a surface where the bridge chips 112 are disposed. Here, the circuit layer 115 may be exposed to UV laser, causing the release layer 21 and the carrier 20 to be peeled off and separated from the circuit layer 115.

Please refer to FIG. 1E, then, a singulation process is executed to obtain multiple interposer modules 110 (singulated form), wherein the singulation process may be performed by means of a rotating blade or laser beam cutting. After executing the singulation process and before joining to the substrate 120, an inspection and testing step may be executed on the singulated interposer modules 110 to reduce the probability of poor quality affecting the chip modules 130 subsequently joined on them, but the present disclosure is not limited thereto.

Please refer to FIG. 1F, a substrate 120 is provided, and the interposer module 110 (singulated form) is disposed on the substrate 120. Then, the chip module 130 is disposed on the interposer module 110, causing the chip module 130 to be electrically connected to the substrate 120 through the interposer module 110. In this embodiment, the chip module 130 is exemplified as composed of multiple discrete chiplets (FIG. 1F schematically illustrates three chiplets 131). Here, the three chiplets 131 may have the same function or different functions according to actual design requirements, the present disclosure does not impose any restrictions. For example, the chiplets 131 may be logic chips, memory chips, or a combination thereof.

In this embodiment, multiple external terminals 121 are further formed on the surface (such as the bottom surface) of the substrate 120 relative to the interposer module 110, so as to connect (such as electrically connect or dummy connect) with other components in subsequent processes.

In FIG. 1F, the interposer module 110 may be joined to the substrate 120 through the multiple conductive terminals 116a and the dummy terminals 116b, and the chip module 130 may be joined to the interposer module 110 through the multiple conductive terminals 130a, wherein the chip module 130 is electrically connected to the substrate 120 through the conductive terminals 130a, the circuit layer 115 in the interposer module 110, the conductive connecting components 114 in the interposer module 110, and the conductive terminals 116a. Here, the conductive terminals 116a are exemplified as first conductive terminals, and the conductive terminals 130a are exemplified as second conductive terminals.

It should be noted that both the conductive terminals 116a and the dummy terminals 116b will directly contact the topmost metal layer of the substrate 120 to achieve the effect of stress dispersion. The part of the topmost metal layer connected to the conductive terminals 116a is a functional pad, causing the functional pad to be electrically connected to the functional external terminals 121 thereunder. The part of the topmost metal layer connected to the dummy terminals 116b is a dummy pad, causing the dummy pad not to be electrically connected to the functional external terminals 121 thereunder, or causing the dummy pad to be connected to the dummy external terminals 121 thereunder, but the present disclosure is not limited thereto.

In an embodiment, before joining the interposer module 110, an inspection and testing step may be executed on the substrate 120 to reduce the probability of poor quality affecting the chip module 130 subsequently joined thereon, but the present disclosure is not limited thereto.

In an embodiment, there may be gaps between adjacent chiplets 131 in the chip module 130, and signal transmission may be performed through the bridge chips 112, but the present disclosure is not limited thereto.

In some embodiments, the substrate 120 may be an ABF substrate or the like. However, it should be noted that the number of dielectric layers and conductive circuit design (such as through-holes, etc.) of the substrate 120 in FIG. 1F are only schematically illustrated. The present disclosure does not limit the type of the substrate 120. As long as the substrate 120 may provide the signal transmission function required in the product, the substrate 120 falls within the scope to be protected by the present disclosure.

Please refer to FIG. 1G, an encapsulant 140 is formed to encapsulate the chip module 130 and the interposer module 110 and directly contact the substrate 120. For example, the bottom surface 140b of the encapsulant 140 may be coplanar with the top surface 120t of the substrate 120. In addition, a portion of the encapsulant 140 may be extended from above the substrate 120 to above the interposer module 110. Here, the encapsulant 140 is exemplified as a first encapsulant. In addition, the encapsulant 113 and the encapsulant 140 may be formed through a molding process using liquid compound or granule type solid molding compound.

After the aforementioned process, the fabrication of the package structure PKG1 of this embodiment is substantially completed. Since the chip module 130 is not first disposed on the wafer-level interposer module 110, and most of the processes for the package structure PKG1 have been completed when the chip module 130 is disposed, it is possible to reduce the number of processes the chip module 130 goes through, lowering the risk of yield loss during the process. In the meantime, based on the protection provided by the encapsulant 140, the overall structural strength may be improved. Accordingly, the yield of the package structure PKG1 of this embodiment is effectively improved, thereby ensuring good quality thereof. Here, the wafer-level interposer module 110 is exemplified as the unsingulated interposer module 110 shown in FIG. 1D.

Moreover, the unsingulated interposer wafer warpage and unevenness caused by multi layers (such as dielectric layer, RDL layer and and/or molding layer) may impact the chiplets placement process window and yield. On the other hand, it is also possible to cause problems where the conductive terminals on the chip cannot effectively align with the underlying interposer structure, thus resulting in higher process risks and more difficult yield control. Under the process step design from FIG. 1A to FIG. 1G of the present disclosure, it may be limited that the fine-pitch chip joining process may be performed in a smaller area (the size of the singulated interposer module 110). Therefore, a wider process window/margin may be achieved, thereby reducing the probability of the aforementioned problems occurring.

In this embodiment, the encapsulant 140 wraps the connecting terminals 116 (including conductive terminals 116a and dummy terminals 116b) and conductive terminals 130a, causing the connecting terminals 116 (including conductive terminals 116a and dummy terminals 116b) and conductive terminals 130a to be recessed within the encapsulant 140. Furthermore, as shown in FIG. 1G, the protective member wrapping the connecting terminals 116 (including conductive terminals 116a and dummy terminals 116b) and the conductive terminals 130a may be a part of the encapsulant 140. In this way, protection may be provided simultaneously to components such as the interposer module 110, the chip module 130, the connecting terminals 116 (including conductive terminals 116a and dummy terminals 116b) and the conductive terminals 130a in one step, thereby significantly reducing material costs and/or process cycle time. However, the present disclosure is not limited to this.

In an embodiment, after forming the encapsulant 140, the process further includes executing a planarization process, such as a chemical-mechanical polishing (CMP) process, a mechanical grinding process, or similar processes, so as to expose the top surface 130t of the chip module 130 from the encapsulant 140, and to make the top surface 130t of the chip module 130 coplanar with the top surface 140t of the encapsulant 140. In this way, the heat dissipation capability of the chip module 130 may be improved. Moreover, due to the design of the encapsulant 140, the chip module 130 does not need to be thinned in advance. The thickness in the stacking direction (direction Z) may be effectively reduced in one step through the aforementioned planarization process, thus more accurately controlling the thickness within the required range. However, the present disclosure is not limited to this.

In an embodiment, the thickness 140T of the encapsulant 140 may be equal to the vertical distance from the top surface 130t of the chip module 130 to the top surface 120t of the substrate 120. However, the present disclosure is not limited to this.

In an embodiment, after forming the encapsulant 140, no singulation process is executed. Therefore, the encapsulant 140 may have a different size from the substrate 120. For example, the outer sidewall 140s of the encapsulant 140 may be between the outer sidewall 110s of the interposer module 110 and the outer sidewall 120s of the substrate 120. In the embodiment, the outer sidewall 140s of the encapsulant 140 may be entirely between the outer sidewall 110s of the interposer module 110 and the outer sidewall 120s of the substrate 120. In other words, the encapsulant 140 may expose a partial area A on the substrate 120, so as to facilitate the subsequent arrangement of other components. However, the present disclosure is not limited to this.

In an embodiment, since the encapsulant 113 of the interposer module 110 is exposed after executing the singulation process, the encapsulant 140 formed in this step may physically cover part of the encapsulant 113 of the interposer module 110 (for example, by direct contact). However, the present disclosure is not limited to this. In other embodiments, the encapsulant 140 may indirectly cover the encapsulant 113 of the interposer module 110, such as by having other film layers or components interposed between them.

In an embodiment, the chip module 130 may be composed of multiple discrete chiplets 131. Since the cost of chiplets 131 is relatively high, a probe card test may be executed before placing the chiplets 131 on the interposer module 110 to select known good dies (KGD) among them. In this way, it is possible to avoid the situation where some chiplets 131 in the chip module 130 are damaged, causing other chiplets 131 to be inoperable. However, the present disclosure is not limited to this. Here, a KGD may be a semiconductor chip that has been tested, inspected, and qualified in terms of functionality and reliability, and is known to be able to achieve all designed attributes and operational states when power is applied thereto.

In an embodiment, during the manufacturing process, a recess (not shown) may be formed on the top surface 120t of the substrate 120 (such as on the solder mask of the topmost insulation layer), and the encapsulant 140 may fill into this recess to improve the adhesion between the encapsulant 140 and the substrate 120, reducing the probability of delamination. However, the present disclosure is not limited to this.

In some embodiments, the conductive bumps 112a, the connecting terminals 116, and the conductive terminals 130a may respectively include conductive pillars, conductive solder balls, or combinations thereof. The material may be copper or similar materials. The solder balls may be formed by means of a ball placement process and/or a reflow process. However, the present disclosure is not limited to this. In some alternative embodiments, the conductive bumps 112a, the connecting terminals 116, and the conductive terminals 130a may use other possible forms or shapes based on design requirements, and may have the same or different configurations among themselves.

In some embodiments, the encapsulant 113 and the encapsulant 140 may be respectively formed of insulating materials such as epoxy resin or other suitable resins. For example, the encapsulant 113 and the encapsulant 140 may be molding compounds formed by means of a molding process. However, the present disclosure is not limited to this. The encapsulant 113 and the encapsulant 140 may be formed with other suitable materials and methods, and may have the same or different configurations between them.

It should be noted that the following embodiments adopt the same component numbers and partial content as the above-mentioned embodiments, where the same or similar numbers are used to represent the same or similar components, and the explanation of the same technical content is omitted. For the explanation of the omitted parts, please refer to the previous embodiments. The following embodiments will not repeat the redundant descriptions.

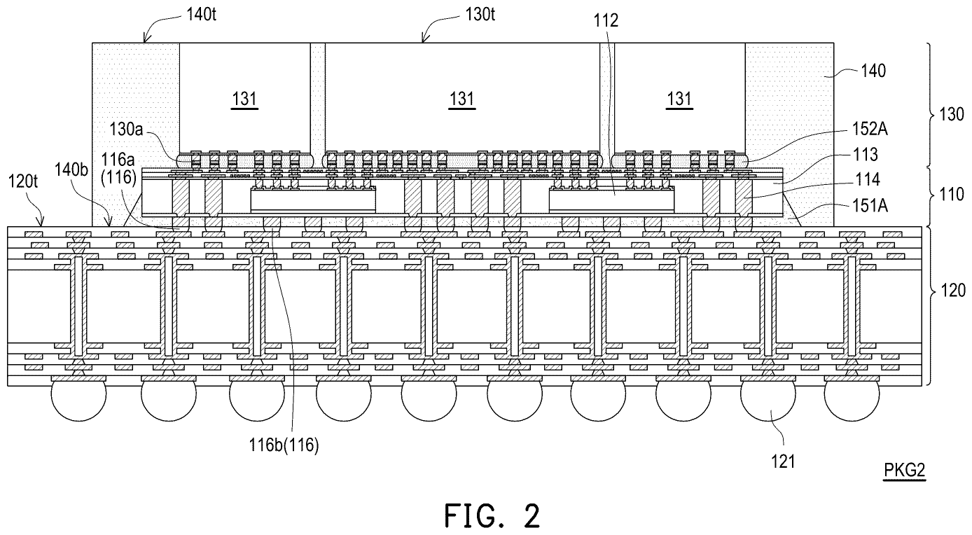

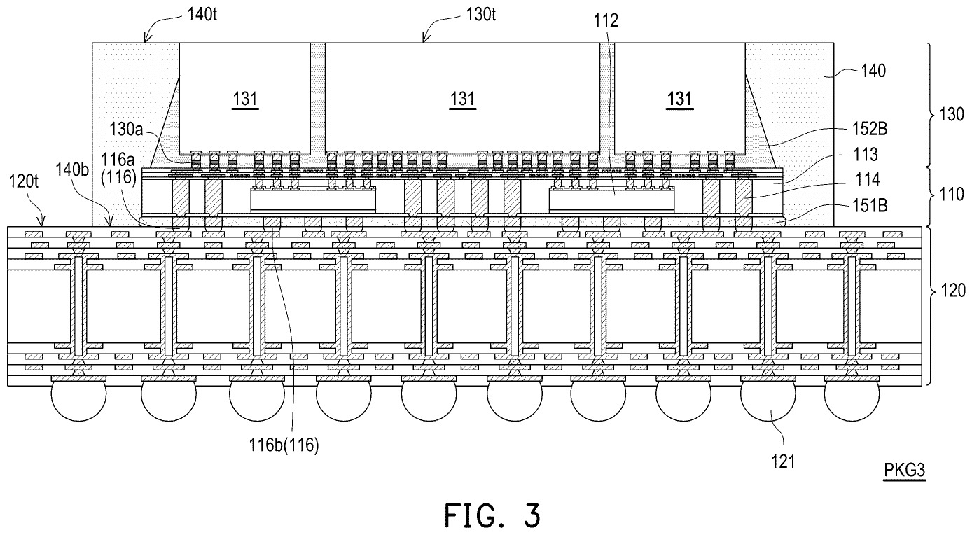

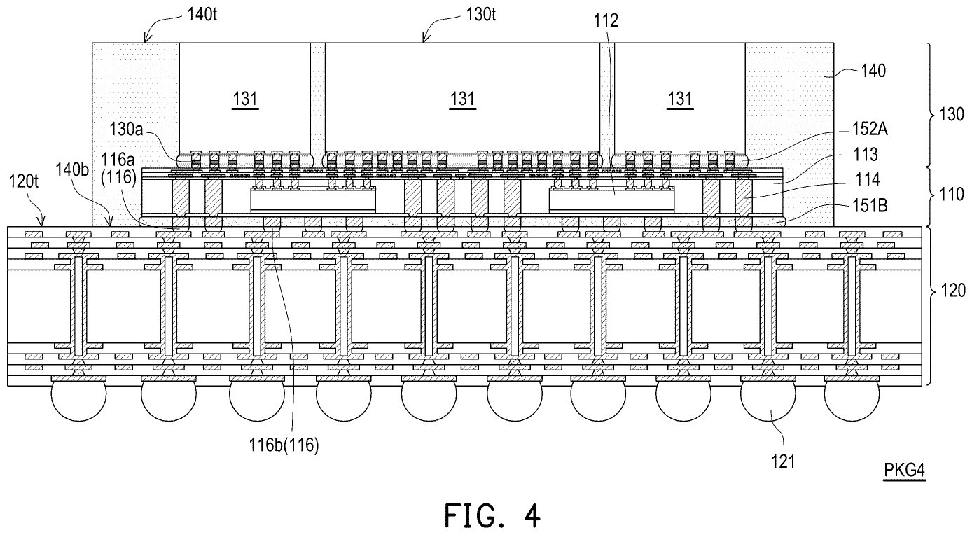

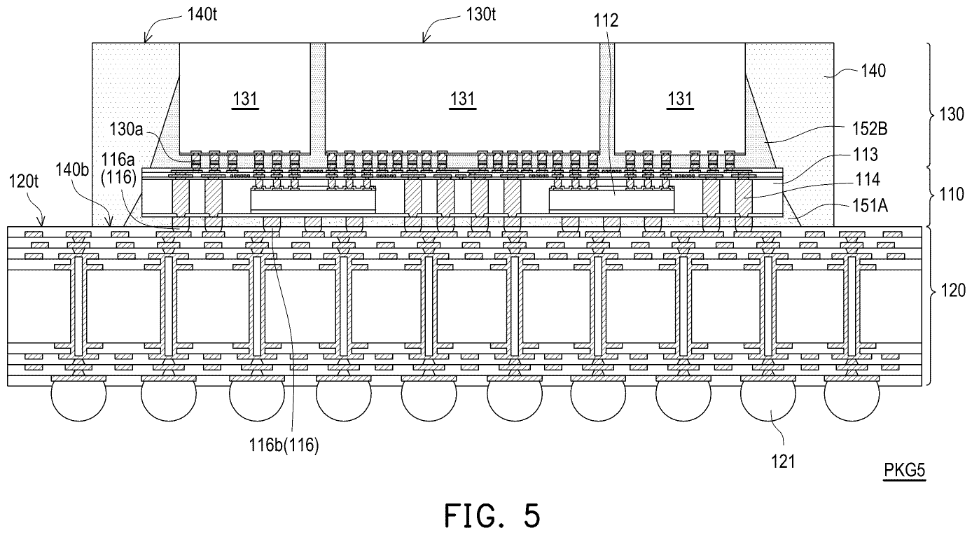

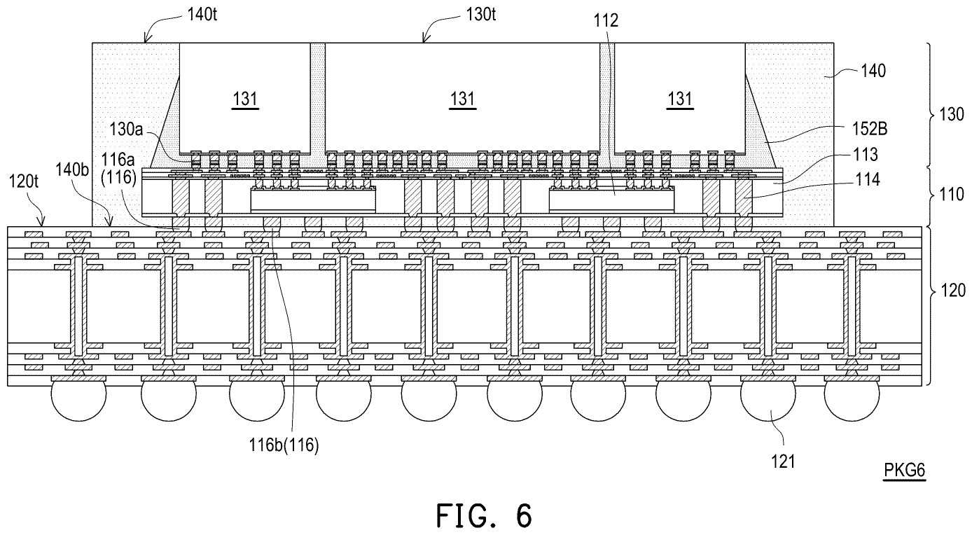

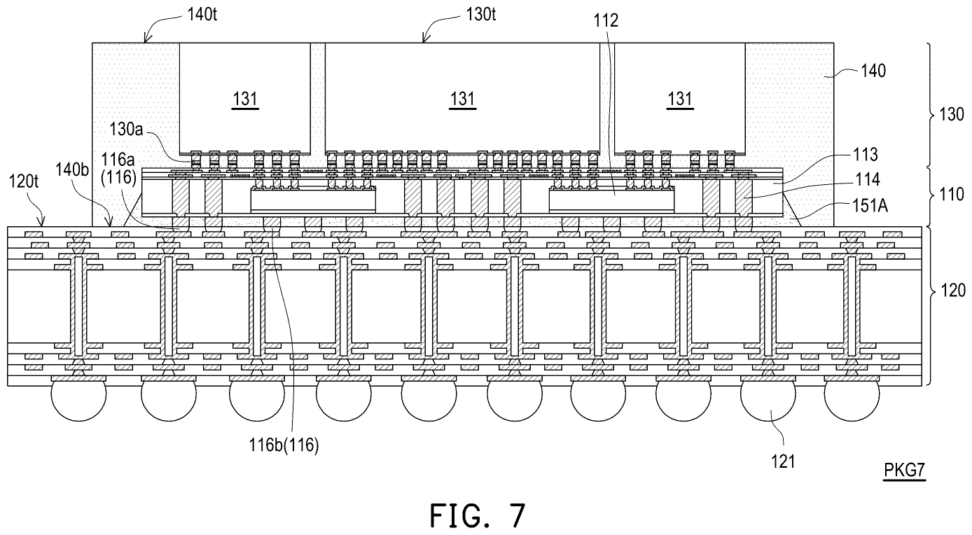

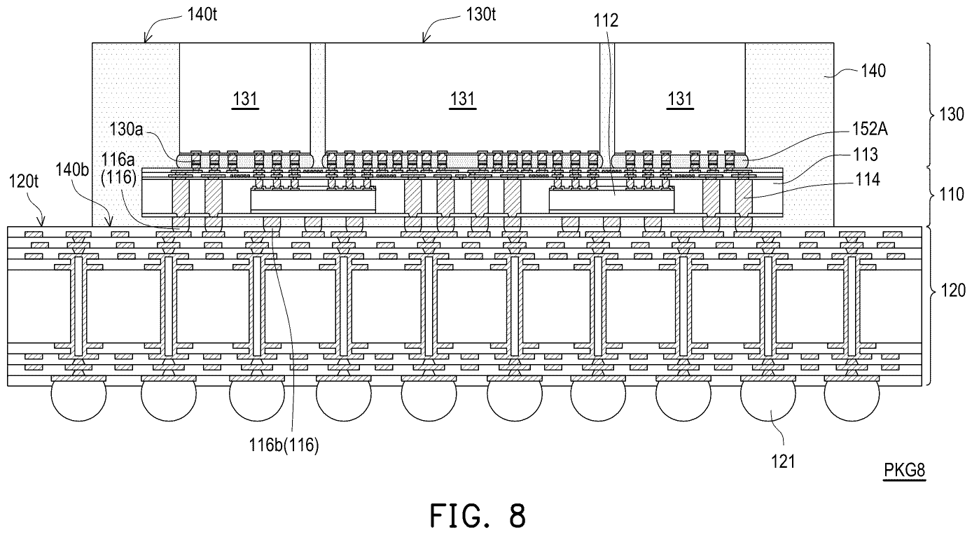

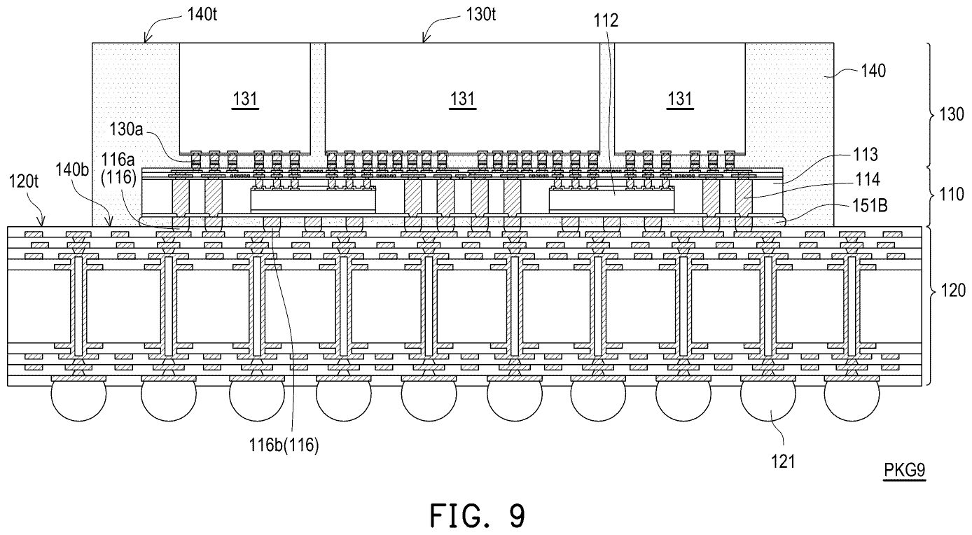

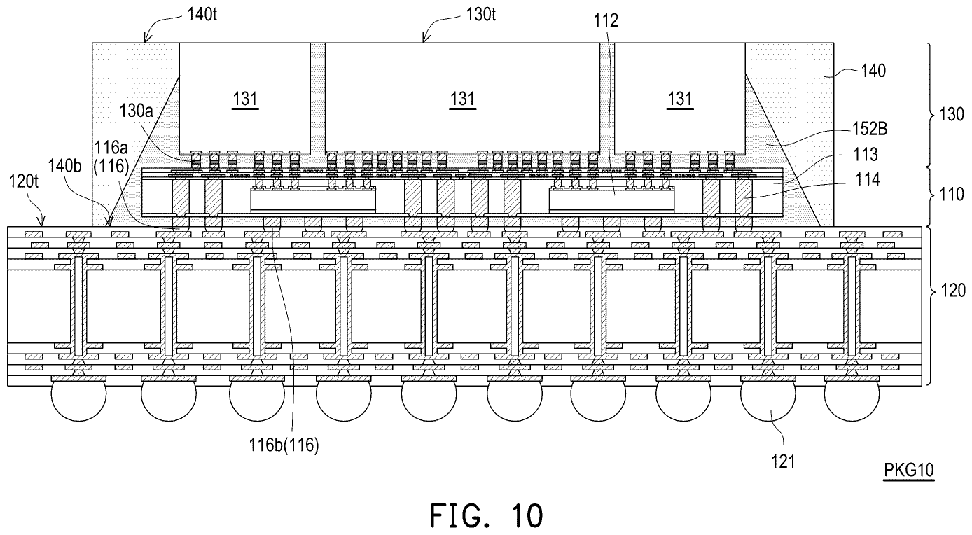

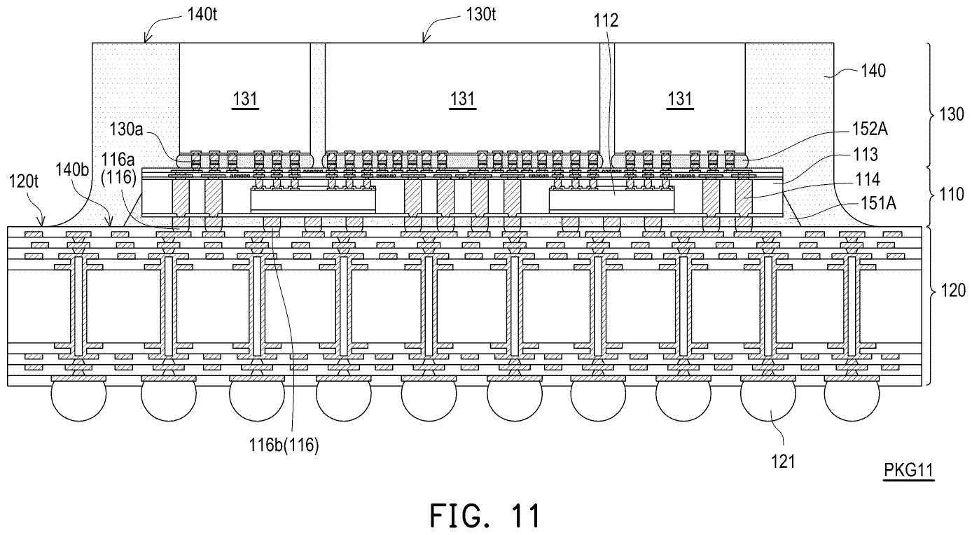

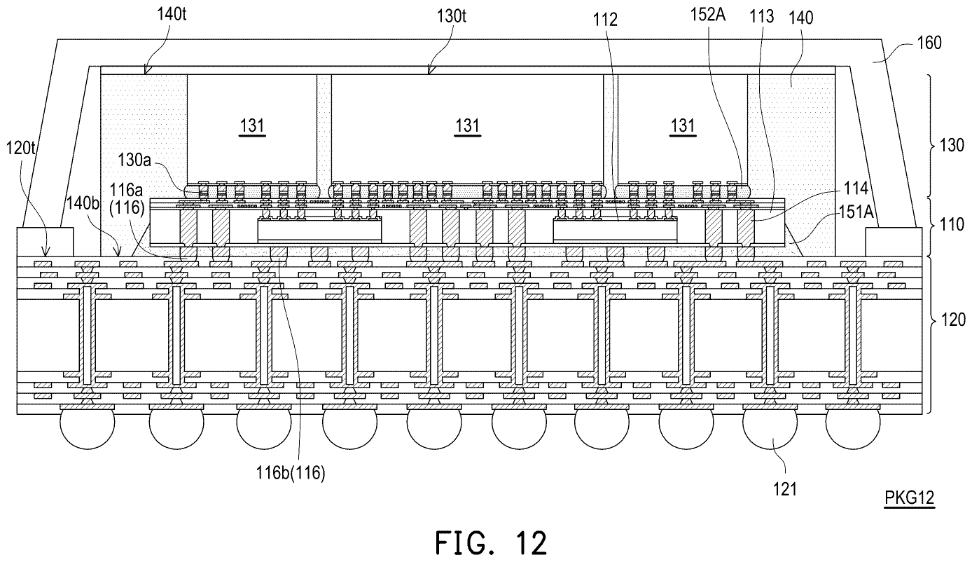

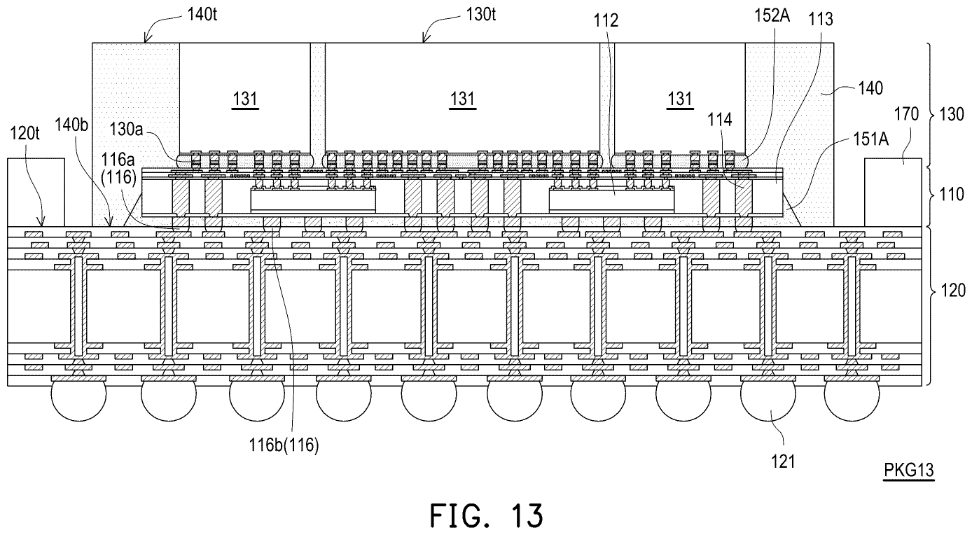

FIG. 2, FIG. 3, FIG. 4, FIG. 5, FIG. 6, FIG. 7, FIG. 8, FIG. 9, FIG. 10, FIG. 11, FIG. 12, and FIG. 13 are partial cross-sectional views of package structures according to some embodiments of the present disclosure.

Please refer to FIG. 2. In this embodiment, the package structure PKG2 resembles the package structure PKG1, with the difference being: the connecting terminals 116 (including conductive terminals 116a and dummy terminals 116b) are wrapped by means of the protective member 151A, and the conductive terminals 130a are wrapped by means of the protective member 152A, where the protective member 151A and the protective member 152A are formed before the encapsulant 140 is formed. In other words, the protective member 151A and the protective member 152A of this embodiment are not part of the encapsulant 140.

Moreover, as shown in FIG. 2, the material of the protective member 151A is different from the material of the protective member 152A. For example, the material of the protective member 151A may be selected from capillary underfill material (CUF), while the material of the protective member 152A may be selected from non-conductive film (NCF). For instance, in FIG. 2, since the CUF material is formed by executing a dispensing process, the CUF material fills the gaps between the connecting terminals 116 by means of the fluidity of the adhesive and capillary effect, while also overflowing upwards to form on the sidewall of the interposer module 110. Therefore, the protective member 151A will have a trapezoidal contour. On the other hand, since the NCF is formed by executing a film attachment process, before the chip module 130 is joined to the interposer module 110, the conductive terminals 130a on the chiplets 131 are first attached to a sheet-like dry film material, and then the flip-chip bonding of the chiplets 131 is executed through heat and pressure. In the meantime, the conductive terminals 130a are protected by the protective member 152A. Therefore, when using the NCF, the flip-chip bonding method is thermal compression bonding (TCB), and the protective member 152A may form an arc-shaped edge caused by the squeezing of the dry film material. In this way, the protective member 152A does not wrap the sidewall (for example, the upper half part) of the chiplets 131. In other words, based on the selection of different materials, the protective member 151A and the protective member 152A may have different configurations, but the present disclosure is not limited to this.

In an embodiment, the CUF material and the NCF may have their respective advantages in different situations. For example, when the chiplets 131 have a high aspect ratio, such as when the chiplets 131 have large sizes and/or there are small gaps between the chiplets 131 (e.g., 50 microns to 150 microns), the CUF material easily wraps the sidewalls between the chiplets 131 and has a large contact area with the substrate material (such as silicon) in the chiplets 131. In this way, when there are situations such as poor adhesion, trapped voids, and/or insufficient strength of the CUF material itself between the CUF material and the substrate material, delamination and cracks might occur during reliability tests, reducing product reliability. In this case, the NCF has its advantages as it can avoid the aforementioned risks. On the other hand, since the NCF is more difficult to wrap higher conductive terminals, in cases where the height (solder joint height) of the conductive terminals 130a after the chiplets 131 joining is higher (such as a height greater than 40 microns), the CUF material has its advantages. Therefore, the present disclosure does not limit the material of the protective member, and the material may be determined according to actual design requirements.

In this embodiment, the NCF used between the chiplets 131 and the interposer module 110 may reduce the size of the interposer module 110, but the present disclosure is not limited to this. In other embodiments, when the NCF is adopted between the interposer module 110 and the substrate 120, it is possible to reduce the size of the substrate 120.

Please refer to FIG. 3. In this embodiment, the package structure PKG3 resembles the package structure PKG2, with the difference being: the protective member 151B is selected from the NCF, while the protective member 152B is selected from the CUF material. Therefore, the protective member 151B has an arc-shaped edge, while the protective member 152B has a trapezoidal contour. Furthermore, in this embodiment, when using the CUF material, the flip-chip bonding method may involve first placing the chiplets 131 in position, then joining them through reflow, followed by forming the CUF material through a dispensing process. In other words, the protective member 152B may be formed after the chip module 130 is joined to the interposer module 110. Moreover, in this embodiment, due to the smaller gaps between the chiplets 131, the capillary effect is more significant. Therefore, the protective member 152B between the chiplets 131 may climb higher compared to the protective members 152B on both sides. However, the present disclosure is not limited to this.

Please refer to FIG. 4. In this embodiment, the package structure PKG4 resembles the package structure PKG2 and the package structures PKG3, with the difference being: the protective member 151B selected from NCF is used to wrap the connecting terminals 116, and the protective member 152A selected from the NCF is used to wrap the conductive terminals 130a.

Please refer to FIG. 5. In this embodiment, the package structure PKG5 resembles the package structure PKG2 and the package structure PKG3, with the difference being: the protective member 151A selected from the CUF material is used to wrap the connecting terminals 116, and the protective member 152B selected from the CUF material is used to wrap the conductive terminals 130a.

Please refer to FIG. 6. In this embodiment, the package structure PKG6 resembles the package structure PKG1 and the package structure PKG3, with the difference being: the encapsulant 140 is adopted to wrap the connecting terminals 116, and the protective member 152B selected from the CUF material is adopted to wrap the conductive terminals 130a.

Please refer to FIG. 7. In this embodiment, the package structure PKG7 resembles the package structure PKG1 and the package structure PKG2, with the difference being: the protective member 151A selected from the CUF material is adopted to wrap the connecting terminals 116, and the encapsulant 140 is adopted to wrap the conductive terminals 130a.

Please refer to FIG. 8. In this embodiment, the package structure PKG8 resembles the package structure PKG1 and the package structure PKG2, with the difference being: the encapsulant 140 is adopted to wrap the connecting terminals 116, and the protective member 152A selected from the NCF is adopted to wrap the conductive terminals 130a.

Please refer to FIG. 9. In this embodiment, the package structure PKG9 resembles the package structure PKG1 and the package structure PKG3, with the difference being: the protective member 151B selected from the NCF is adopted to wrap the connecting terminals 116, and the encapsulant 140 is adopted to wrap the conductive terminals 130a.

Please refer to FIG. 10. In this embodiment, the package structure PKG10 resembles the package structure PKG3, with the difference being: the protective member 152B selected from the CUF material is adopted to wrap both the connecting terminals 116 and the conductive terminals 130a in one step.

Please refer to FIG. 11. In this embodiment, the package structure PKG11 resembles the package structure PKG2, with the difference being: the encapsulant 140 includes an overflow portion, causing the interface between the outer sidewall of the encapsulant 140 and the substrate 120 to have a curvature (for example, the interface between the outer sidewall of the encapsulant 140 and the substrate 120 is not vertical). As a result, the adhesion between the encapsulant 140 and the substrate 120 may be improved.

Please refer to FIG. 12. In this embodiment, the package structure PKG12 resembles the package structure PKG2, with the difference being: the package structure PKG12 further includes a lid 160, wherein the lid 160 at least covers the back surface of the chip module 130 relative to the active surface. Therefore, the lid 160 may protect the electronic components in the package structure PKG12, and may also serve as a heat dissipation component to provide additional heat dissipation function. In an embodiment, multiple cavities may be formed between the lid 160 and the encapsulant 140.

Please refer to FIG. 13. In this embodiment, the package structure PKG13 resembles the package structure PKG2, with the difference being: the package structure PKG13 further includes a metal ring 170, wherein the metal ring 170 may be located on the top surface 120t of the substrate 120 and surrounds the chip module 130. Therefore, the metal ring 170 may protect the electronic components in the package structure PKG13, and may also serve as a reinforcing component to provide additional support function.

In the above-mentioned embodiments, the back surface 130t of the chip module 130 may be further deposited to form a backside metal (BSM) or set with a thermal interface material (TIM) (not shown), wherein the backside metal may be continuously formed on the coplanar surface formed by the encapsulant 140 and the chip module 130, so as to further improve heat dissipation capability. However, the present disclosure is not limited to this. Here, the material of the backside metal may be any suitable metal material with excellent heat dissipation efficiency, and the present disclosure does not impose any restrictions on it.

In summary, due to the reduction in the number of process steps that the chip module undergoes, the risk of defect rate during the manufacturing process is lowered. In the meantime, based on the protection provided by the encapsulant, the overall structural strength may be improved. Accordingly, the yield of the package structure in this embodiment is effectively improved, thereby ensuring good quality of the package structure.

Although the present disclosure has been disclosed in the above embodiments, it is not intended to limit the present disclosure. Any person skilled in the art may make minor modifications and refinements without departing from the spirit and scope of the present disclosure. Therefore, the scope to be protected by of the present disclosure should be defined by the appended claims.

What is claimed is:

1. A package structure, comprising:
a substrate;
an interposer module, disposed on the substrate;
a chip module, disposed on the interposer module, wherein the chip module is electrically connected to the substrate through the interposer module; and
a first encapsulant, encapsulating the chip module and the interposer module and directly contacting the substrate, and a bottom surface of the first encapsulant is coplanar with a top surface of the substrate.

2. The package structure as claimed in claim 1, wherein the first encapsulant exposes a top surface of the chip module.

3. The package structure as claimed in claim 1, wherein an outer sidewall of the first encapsulant is between an outer sidewall of the interposer module and an outer sidewall of the substrate.

4. The package structure as claimed in claim 1, wherein a thickness of the first encapsulant is equal to a vertical distance from a top surface of the chip module to the top surface of the substrate.

5. The package structure as claimed in claim 1, wherein the first encapsulant covers a second encapsulant of a part of the interposer module.

6. The package structure as claimed in claim 1, further comprising a plurality of first conductive terminals between the substrate and the interposer module, and a plurality of second conductive terminals between the interposer module and the chip module, wherein the plurality of first conductive terminals and the plurality of second conductive terminals are recessed within the first encapsulant.

7. The package structure as claimed in claim 6, wherein the plurality of first conductive terminals and the plurality of second conductive terminals are wrapped by a first protective member and a second protective member, respectively.

8. The package structure as claimed in claim 7, wherein a material of the first protective member and a material of the second protective member are respectively selected from a non-conductive film, a capillary underfill material, the first encapsulant or a combination thereof, and the materials of the first protective member and the second protective member are the same or different.

9. The package structure as claimed in claim 1, wherein the first encapsulant comprises an overflow portion, causing a curvature to be formed at an interface between an outer sidewall of the first encapsulant and the substrate.

10. A method of manufacturing a package structure, comprising:
providing a substrate;
providing an interposer module, wherein the interposer module is in a singulated manner;
disposing the interposer module on the substrate;
providing a chip module;
disposing the chip module on the interposer module, wherein the chip module is electrically connected to the substrate through the interposer module; and
forming a first encapsulant to encapsulate the chip module and the interposer module and directly contact the substrate.

11. The method of manufacturing the package structure as claimed in claim 10, further comprising executing a planarization process after forming the first encapsulant to expose a top surface of the chip module.

12. The method of manufacturing the package structure as claimed in claim 10, wherein a singulation process is not executed after forming the first encapsulant.

13. The method of manufacturing the package structure as claimed in claim 10, further comprising:
joining the interposer module and the substrate through a plurality of first conductive terminals;
joining the chip module and the interposer module through a plurality of second conductive terminals; and
wrapping the plurality of first conductive terminals and the plurality of second conductive terminals respectively through a first protective member and a second protective member.

14. The method of manufacturing the package structure as claimed in claim 13, wherein the first protective member and the second protective member are respectively formed by executing a dispensing process or a film attaching process.

15. The method of manufacturing the package structure as claimed in claim 13, wherein the second protective member is formed before disposing the chip module on the interposer module, or the second protective member is formed after disposing the chip module on the interposer module.

16. The method of manufacturing the package structure as claimed in claim 13, wherein the first protective member and/or the second protective member is a part of the first encapsulant.

17. The method of manufacturing the package structure as claimed in claim 10, wherein the step of forming the interposer module comprises:
disposing a plurality of bridge chips on a carrier;
forming a second encapsulant to encapsulate the plurality of bridge chips;
removing the carrier; and
executing a singulation process.

18. The method of manufacturing the package structure as claimed in claim 11, wherein the first encapsulant exposes a partial area on the substrate.

19. The method of manufacturing the package structure as claimed in claim 10, wherein the interposer module is disposed on the substrate before disposing the chip module on the interposer module.
